(19) United States
(12) Patent Application Publication
(10) Pub. No.: US 2025/0115809 A1
(43) Pub. Date: Apr. 10, 2025

(54) COMPOSITION, ITS USE AND A PROCESS FOR SELECTIVELY ETCHING SILICON-GERMANIUM MATERIAL

(71) Applicant: BASF SE, Ludwigshafen Am Rhein (DE)

(72) Inventors: Francisco Javier LOPEZ VILLANUEVA, Ludwigshafen am Rhein (DE); Sven HILDEBRANDT, Muelheim an der Ruhr (DE); Andreas KLIPP, Ludwigshafen am Rhein (DE); Chih Hui LO, Taoyuan City (TW); Mei Chin SHEN, Taoyuan City (TW)

(21) Appl. No.: 18/730,007

(22) PCT Filed: Feb. 13, 2023
(86) PCT No.: PCT/EP23/53478

§ 371 Date: Jul. 18, 2024

(30) Foreign Application Priority Data
Feb. 23, 2022 (EP) 22158245.5
Oct. 14, 2022 (EP) 22201548.9

(51) Int. Cl. C09K 13/08; H01L 21/306

(52) U.S. Cl. CPC C09K 13/08; H01L 21/30604

(57) ABSTRACT

Disclosed herein is a composition for selectively etching a first silicon germanium layer having a first germanium content in the presence of a silicon layer or a second silicon germanium layer having a second germanium content, where the first germanium content is higher than the second germanium content, the composition including:
(a) from 0.1 to 10% by weight of an oxidizing agent;
(b) from 1 to 20% by weight of an etchant including a source of fluoride ions;
(c) from 0.001 to 3% by weight of a selectivity enhancer of formula Si

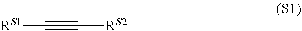

(d) from 0.001 to 3% by weight of an additional selectivity enhancer of formula S41

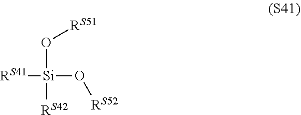

or derivatives thereof obtained by homocondensation of the compounds of formula S41 or by co-condensation of the compounds of formula S41 with silanes of formula S42 in a weight ratio of 0.1 or more

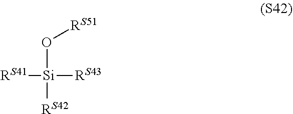

and
(e) water.

The present invention relates to a composition, its use and a process for selectively etching silicon-germanium material at a surface of a microelectronic device substrate, relative to etching a silicon material or a silicon-germanium material that has a lower germanium content at the same surface.

### BACKGROUND OF THE INVENTION

Steps of preparing certain microelectronic devices, e.g., integrated circuits, may include selectively removing silicon-germanium (SiGe) material from a surface that contains the SiGe in combination with silicon (Si). According to certain example fabrication steps, SiGe may be used as a sacrificial layer in a structure that also contains silicon. Based on such fabrication steps, advanced device structures may be prepared, such as silicon nanowires and silicon on nothing (SON) structures. Steps in these processes include epitaxial deposition of a structure of alternating layers of Si and SiGe, followed by patterning and, eventually, selective lateral etching to remove the SiGe layers and generate a three-dimensional silicon structure.

In certain specific methods of preparing a field effect transistors (FET) for an integrated circuit, Si and SiGe materials are deposited as layers onto a substrate, i.e., as an “epitaxial stack” of Si and SiGe. The layers are subsequently patterned using standard techniques, such as by use of a standard lithographically generated mask. Next, a directional isotropic etch may be useful to laterally etch away the sacrificial SiGe material, leaving behind a silicon nanowire or sheet structure.

In other applications SiGe having a low Ge content may have to be etched against SiGe having a higher Ge content.

To enable smaller structures within Semiconductor structures electronic industry is searching for solutions to remove SiGe layers selectively against amorphous or crystalline silicon. This is needed to realize well defined nanowire or nanosheet structures.

EP 3 447 791 A1 discloses an etching solution for the selective removal of silicon-germanium over poly silicon from a microelectronic device comprising water, an oxidizer, a water-miscible organic solvent, a fluoride ion source, and optionally a surfactant. Example 5 discloses a composition comprising H₂O₂, NH₄F, butyl diclycol, citric acid, and Surfynol® 485, that is a polyethoxylated dialkyl acetylene compound having an ethylene oxide content (mole) of 30 and aids in the suppression of poly Si etch rate.

Nonpublished International patent application No. PCT/EP2021/072975 discloses a composition for selectively etching a layer comprising a silicon germanium alloy (SiGe) in the presence of a a layer comprising silicon, the composition comprising 5 to 15% by weight of an oxidizing agent, 5 to 20% by weight of an etchant comprising a source of fluoride ions, 0.001 to 3% by weight of an acetylenic hydroxy compound as selectivity enhancer, and water.

However, the state-of-the-art solutions are not able to fulfil all requirements since they have a too high SiOₓ, SiON or SiN etch rate.

It is therefore an object of the invention to keep the SiGe/Si selectivity and to increase the SiGe/SiOₓ, the SiGe/SiON or the SiGe/SiN selectivity, particularly the SiGe/SiOₓ selectivity.

It is a further object of the invention to increase the selectivity of etching a SiGe with a higher Ge content against SiGe with a lower Ge content while keeping or increasing the SiGe/SiOₓ, the SiGe/SiON or the SiGe/SiN selectivity, particularly the SiGe/SiOₓ selectivity.

### SUMMARY OF THE INVENTION

It has now been found that the use of low amounts of a silane compound and its derivatives significantly and selectively improves the SiGe/Si selectivity against SiOₓ, SiON or SiN.

Therefore, one embodiment of the present invention is a composition for selectively etching a first silicon germanium layer having a first germanium content in the presence of a silicon layer or a second silicon germanium layer having a second germanium content, wherein the first germanium content is higher than the second germanium content, the composition comprising:
(a) 0.1 to 10% by weight of an oxidizing agent;
(b) 1 to 20% by weight of an etchant comprising a source of fluoride ions;
(c) 0.001 to 3% by weight of a selectivity enhancer of formula S1

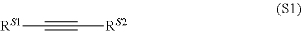

(d) 0.001 to 3% by weight of an additional selectivity enhancer of formula S41

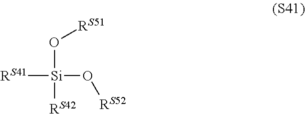

or derivatives thereof obtainable by homocondensation of the compounds of formula S41 or by co-condensation of the compounds of formula S41 with silanes of formula S42 in a weight ratio of 0.1 or more

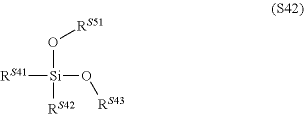

and
(e) water;
wherein
R^{S1} is selected from X^{S}—OH and Y^{S}—(CO)—OH;
R^{S2} is selected from (i) R^{S1}, (ii) H, (iii) C₁ to C₁₀ alkyl, (iv) C₁ to C₁₀ alkenyl, (v) C₁ to C₁₀ alkynyl, and (vi) —X^{S1}—(O—C₂H₃R^{S6})ₘ—OR^{S6};
R^{S6} is selected from H and C₁ to C₆ alkyl;
R^{S41} is C₁ to C₆ alkyl which may be unsubstituted or substituted by —NR^{S61}R^{S62} or —OR^{S61};
R^{S42}, R^{S43} are independently selected from C₁ to C₆ alkoxy and C₁ to C₆ alkyl which both may be unsubstituted or substituted by —NR^{S61}R^{S62} or —OR^{S61};
R^{S51}, R^{S52} are independently selected from C₁ to C₆ alkyl which may be unsubstituted or substituted by —NR^{S61}R^{S62} or —OR^{S61};
R^{S61}, R^{S62} are independently selected from H and C₁ to C₆ alkyl; X^{S} is selected from a linear or branched C₁ to C₁₀ alkanediyl, a linear or branched C₂ to C₁₀ alkenediyl, a linear or branched C₂ to C₁₀ alkynediyl, and —X^{S1}—(O—C₂H₃R^{S6})ₘ—;
Y^{S} is selected from a chemical bond and X^{S};
X^{S1} is a C₁ to C₈ alkanediyl; and
m is an integer of from 1 to 30, preferably 10.

It was particularly surprising that the etching composition according to the invention is suited to allow for a very controlled and selective etching of layers comprising or consisting of SiGe alloys, preferably of a SiGe25 layer, even of thin or ultra-thin layers comprising germanium (“Ge layers”), particularly layers comprising or consisting of SiGe alloys, while at the same time not or not significantly compromising layers comprising or consisting of silicon (Si), particularly amorphous or crystalline silicon, most particularly crystalline silicon. Particularly the selectivity of SiGe/SiOₓ, SiGe/SiON and/or SiGe/SiN etching, particularly SiGe/SiOₓ can be significantly improved.

Another embodiment of the present invention is the use of a composition as described herein for selectively etching a first silicon germanium layer having a first germanium content in the presence of a silicon layer or a second silicon germanium layer having a second germanium content and optionally a silicon oxide layer, wherein the first germanium content is higher than the second germanium content.

Yet another embodiment of the present invention is a process of selectively removing a first silicon germanium alloy layer having a first germanium content from a surface of a microelectronic device relative to a silicon layer or a second silicon germanium alloy layer having a second germanium content and and optionally a silicon oxide layer, wherein the first germanium content is higher than the second germanium content, the process comprising:
(a) providing a microelectronic device surface that includes the layer comprising the silicon germanium alloy and the silicon layer and optionally the silicon oxide layer,
(b) providing a composition as described herein, and
(c) contacting the surface with the composition for a time and at a temperature effective to selectively remove the layer comprising silicon-germanium relative to the layer comprising or consisting of Si and optionally the silicon oxide layer.

Yet another embodiment of the present invention is a process for the manufacture of a semiconductor device, comprising the process of selectively removing the first silicon germanium alloy layer having the first germanium content from the surface relative to the silicon layer or the second silicon germanium alloy layer having a second germanium content and optionally a silicon oxide layer as described herein.

### BRIEF DESCRIPTION OF THE FIGURES

FIG. 1 shows a scheme of the non-etched substrate used in the examples;

FIG. 2 shows the resulting substrate after having performed example 1;

FIG. 3 shows the resulting substrate after having performed example 2;

FIG. 4 shows the resulting substrate after having performed example 3;

FIG. 5 shows the substrate after pretreatment with HF and before etching.

FIG. 6 shows the resulting substrate after having performed example 2 without HF pretreatment;

FIG. 7 shows the resulting substrate after having performed example 4;

FIG. 8 shows the resulting substrate after having performed example 6.

### DETAILED DESCRIPTION OF THE INVENTION

The etching composition according to the present invention is particularly useful for etching of silicon-germanium-containing layers in the presence of layers comprising silicon, and particularly useful if an additional layer comprising or consisting of silicon oxide (SiOₓ), SiON and/or SiN are present.

The etching composition comprises (a) 0.1 to 10% by weight of an oxidizing agent; (b) 1 to 20% by weight of an etchant comprising a source of fluoride ions; (c) 0.001 to 3% by weight of a first selectivity enhancer of formula S1

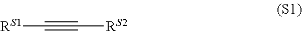

(d) 0.001 to 3% by weight of an additional selectivity enhancer of formula S41

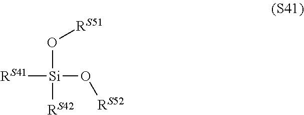

or derivatives thereof obtainable by homocondensation of the compounds of formula S41 or by co-condensation of the compounds of formula S41 with silanes of formula S42 in a weight ratio of 0.1 or more

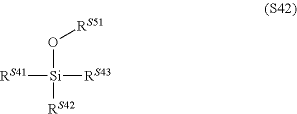

and (d) water, as further described below.

### Definitions

As used herein, a “silicon layer” include, but is not limited to, a layer essentially consisting of elemental silicon, particularly amorphous or crystalline silicon (Si); p-doped silicon; and n-doped silicon. The “silicon layer” excludes silicon germanium alloys (SiGe). The term “essentially consisting of silicon” means that the silicon content in the layer is more than 90% by weight, preferably more than 95% by weight, even more preferably more than 98% by weight. When undoped silicon is used, it is particularly preferred that the silicon layer dos not comprises any other elements than silicon. When n- or p-doped silicon is used, it is particularly preferred that the silicon layer is free of any other elements besides the n- or p-dopants, which may be present in an amount below 10% by weight, preferably below 2% by weight. Preferably, the germanium content of the silicon layer is less than 5% by weight, preferably less than 2% by weight, more preferably less than 1% by weight, even more preferably less than 0.1% by weight. Most preferably the silicon layer comprises no germanium.

As used herein, “silicon oxide layers” or “SiOₓ layers” correspond to layers that were deposited from a silicon oxide precursor source, e.g., TEOS, thermally deposited silicon oxide, or carbon doped oxides (CDO) deposited using commercially available precursors such as SiLK™, AURORA™, CORAL™ or BLACK DIAMOND™. “Silicon oxide” is meant to broadly include SiO&, CDO's, siloxanes and thermal oxides. Silicon oxide or SiOₓ material corresponds to pure silicon oxide (SiO₂) as well as impure silicon oxide including impurities in the structure.

As used herein, the “silicon-germanium layers” or “SiGe layers” correspond to layers essentially consisting of silicon-germanium (SiGe) alloys known in the art. The term “essentially consisting of silicon” means that the SiGe content in the layer is more than 90% by weight, preferably more than 95% by weight, even more preferably more than 98% by weight, and most preferably consists of SiGe. Silicon germanium or SiGe is generally represented by the formula SiₓGe_{y}, wherein x is in a range from about 0.50 to about 0.90, particularly about 0.60 to about 0.85 or about 0.70 to about 0.90, and y is in a range from about 0.10 to about 0.50, particularly from about 0.15 to about 0.40 or about 0.10 to about 0.30, with x+y=1.00. SiGe25 here means that y is 0.25, which is particularly preferred.

As used herein, the term “selectively etching” (or “selective etch rate”) preferably means that upon applying a composition according to the invention to a layer comprising or consisting of a first material, in this case SiGe, in the presence of a layer comprising or consisting of a second material, in this case a material comprising or consisting of silicon, particularly Si, most particularly aSi, the etch rate of said composition for etching the first layer is significantly higher compared to the etch rate of said composition for the second layer. Depending on the substrate to be etched, other layers comprising or consisting of silicon like SiOₓ, SiON or SiN should also not be jeopardized.

SiGe/Si selectivity may be up to more than 500, preferably more than 750, most preferably more than 1000. The SiGe/SiGe selectivity may be up to more than 10, preferably more than 20, most preferably more than 50.

As used herein, the term “layer” means a part of a substrate that was separately disposed on the surface of a substrate and has a distinguishable composition with respect to adjacent layers.

As used herein, “chemical bond” means that the respective moiety is not present but that the adjacent moieties are bridged so as to form a direct chemical bond between these adjacent moieties. By way of example, if in a molecule A-B-C the moiety B is a chemical bond then the adjacent moieties A and C together form a group A-C.

The term “Cₓ” means that the respective group comprises x numbers of C atoms. The term “Cₓ to C_{y} alkyl” means alkyl with a number x to y of carbon atoms and, unless explicitly specified, includes unsubstituted linear, branched and cyclic alkyl. As used herein, “alkyl” refers to linear, branched or cyclic alkyl or a combination thereof. As used herein, “alkanediyl” refers to a diradical of linear, branched or cyclic alkanes or a combination thereof.

All percent, ppm or comparable values refer to the weight with respect to the total weight of the respective composition except where otherwise indicated. The term “wt %” means % by weight.

All cited documents are incorporated herein by reference.

### Oxidizing Agent

The etching composition according to the invention comprises an oxidizing agent. The oxidizing agent, also referred to as “oxidizer”, may be one or more compounds that are capable of oxidizing Germanium within Silicon Germanium alloys.

Preferably the oxidizing agent is different from the the other components of the compsition, particularly different from the etching agent. Therefore, the oxidizing agent is preferably free of any source of fluoride ions.

Oxidizing agents contemplated herein include, but are not limited to, hydrogen peroxide, FeCl₃, FeF₃, Fe(NO₃)₃, Sr(NO₃)₂, CoF₃, MnF₃, oxone (2KHSO₅ KHSO₄ K₂SO₄), periodic acid, iodic acid, vanadium (V) oxide, vanadium (IV,V) oxide, ammonium vanadate, ammonium peroxy-monosulfate, ammonium chlorite, ammonium chlorate, ammonium iodate, ammonium nitrate, ammonium perborate, ammonium perchlorate, ammonium periodate, ammonium persulfate, ammonium hypochlorite, ammonium hypobromite, ammonium tungstate, sodium persulfate, sodium hypochlorite, sodium perborate, sodium hypobromite, potassium iodate, potassium permanganate, potassium persulfate, nitric acid, potassium persulfate, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxymonosulfate, peroxy-monosulfuric acid, ferric nitrate, urea hydrogen peroxide, peracetic acid, methyl-1,4-benzo-quinone (MBQ), 1,4-benzoquinone (BQ), 1,2-benzoquinone, 2,6-dichloro-1,4-benzoquinone (DCBQ), toluquinone, 2,6-dimethyl-1,4-benzoquinone (DMBQ), chloranil, alloxan, N-methyl-morpholine N-oxide, trimethylamine N-oxide, and combinations thereof. The oxidizing species may be introduced to the composition at the manufacturer, prior to introduction of the composition to the device wafer, or alternatively at the device wafer, i.e., in situ.

Preferably the oxidizing agent comprises or consists of a peroxide. Useful peroxides may be but are not limited to hydrogen peroxide or peroxymonosulfuric acid and organic acid peroxides like peroxyacetic acid, and their salts.

The most preferred oxidizing agent is hydrogen peroxide.

The oxidizing agent may be used in an amount of from about 1 to about 20% by weight, preferably from about 1.5 to 14% by weight, more preferably from about 2 to 12% by weight, even more preferably from about 3 to about 11% by weight, most preferably of from about 4 to about 6% by weight, based on the total weight of the composition.

### Etchant

The etching composition according to the invention comprises a source of fluoride ions which may be any compound that is capable of releasing fluoride ions.

Preferably the etchant is different from the other component in the composition, particularly is different from from the oxidizing agent. Therefore, the etchant preferably has no oxidizing capabilities with respect to any of the materials on the surface of the substrate to be treated, particularly Si or SiGe.

Preferred etchants are selected from but not limited to the group consisting of ammonium fluoride, ammonium bifluoride, triethanolammonium fluoride, diglycolammonium fluoride, methyldiethanolammonium fluoride, tetramethylammonium fluoride, triethylamine trihy-drofluoride, hydrogen fluoride, fluoroboric acid, tetrafluoroboric acid, ammonium tetra-fluoro-borate, fluoroacetic acid, ammonium fluoroacetate, trifluoroacetic acid, fluorosilicic acid, ammonium fluorosilicate, tetrabutylammonium tetrafluoroborate, and mixtures thereof. Preferably the etchant consists of one or more, most preferably one of the said compounds.

Most preferably the etchant comprises or consists of ammonium fluoride, ammonium hydrogen fluoride, and hydrogen fluoride. Most preferably the etchant comprises or consists of ammonium fluoride.

The etching compositions according to the invention comprising ammonium fluoride as the etchant have shown a stable and reproducible controlled selective etch rate for etching a layer comprising or consisting of SiGe, in particular SiGe25, in the presence of a layer comprising or consisting of Si.

The etchant may be used in an amount of from about 0.1 to about 14% by weight, preferably of from about 1 to about 12% by weight, more preferably of from about 3 to about 10% by weight, even more preferably of from about 4 to about 10% by weight, most preferably of from about 6 to about 8% by weight, based on the total weight of the composition.

Compositions according to the invention comprising the etchant in the here defined preferred total amounts have shown a superior etch rate, in particular for etching a layer comprising or consisting of SiGe, preferably of SiGe25, and etch rate selectivity, in the presence of a layer comprising or consisting of Si.

### SiGe Selectivity Enhancer

The first SiGe selectivity enhancer (also referred to as “selectivity enhancer”) of formula S1

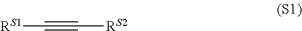

selectively reduces the etch rate of layers comprising or consisting of Si, whereas the etch rate of layers comprising or consisting of SiGe, preferably of SiGe25, are still high, which leads to SiGe/Si, particularly SiG2/a-Si selectivities above 500 or even above 1000.

In formula S1, R^{S1} may be selected from X^{S}—OH and Y^{S}—(CO)—OH, wherein X^{S} may be a linear or branched C₁ to C₁₀ alkanediyl, a linear or branched C₂ to C₁₀ alkenediyl, linear or branched C₂ to C₁₀ alkynediyl, or a polyoxyalkylene group —X^{S1}—(O—C₂H₃R⁶)ₘ—Y^{S1} may be the same as X^{S} or may be a chemical bond. If R^{S1} is a polyoxyalkylene group, X^{S1} may be a C₁ to C₈ alkanediyl, preferably a C₁ to C₆ alkanediyl, most preferably ethanediyl, propanediyl or butanediyl; furthermore, m is integer selected from 1 to 30, preferably from 1 to 20, , most preferably from 1 to 15. The higher m is the lower is the effect of the selectivity enhancer for Si over SiGe. If m is too high, the selectivity enhancers do not sufficiently reduce the a-Si, SiOₓ, SiON or SiN etch rates. For etching SiGe against SiGe a higher m values such as from 5 to 20 or even 20 to 40 are preferred.

R^{S2} may be selected from R^{S1}, preferably R^{S2} is the same as R^{S1} describe above. Alternatively R^{S2} may be (ii) H, (iii) a C₁ to C₁₀ alkyl, (iv) a C₁ to C₁₀ alkenyl, (v) a C₁ to C₁₀ alkynyl, and (vi) —X^{S1}—(O—C₂H₃R^{S6})ₘ—OR^{S6}, wherein X^{S1} is a C₁ to C₆ alkanediyl, preferably ethanediyl, propanediyl or butanediyl; R^{S6} is selected from H and C₁ to C₆ alkyl, preferably H, methyl or ethyl; and m may be an integer of from 1 to 30.

Most preferably R^{S1} and R^{S2} are the same.

In a first preferred embodiment R^{S1} may be X^{S}—OH. Preferably X^{S} may be a C₁ to C alkanediyl, more preferably a C₁ to C₆ alkane-1,1-diyl.

Preferably X^{S} is selected from a C₃ to C₁₀ alkanediyl, more preferably from C₄ to C alkanediyl.

Particularly preferably X^{S} is selected from methanediyl, ethane-1,1-diyl, and ethane-1,2-diyl. In a another preferred embodiment X^{S} is selected from propan-1,1-diyl, butane-1,1-diyl, pentane-1,1-diyl, and hexane-1,1-diyl. In yet another preferred embodiment X^{S} is elected from propane-2-2-diyl, butane-2,2-diyl, pentane-2,2-diyl, and hexane-2,2-diyl. In yet another preferred embodiment X^{S} is elected from propane-1-2-diyl, butane-1,2-diyl, pentane-1,2-diyl, and hexane-1,2-diyl. In yet another preferred embodiment X^{S} is elected from propane-1-3-diyl, butane-1,3-diyl, pentane-1,3-diyl, and hexane-1,3-diyl. Particular preferred groups X^{S} are butane-1,1-diyl, pentane-1,1-diyl, and hexane-1,1-diyl, heptane-1,1-diyl and octane-1,1-diyl.

Preferably the first selectivity enhancer is is a compound of formula S2

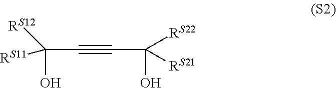

wherein
R^{S11}, R^{S21} are indenpendetly selected from a C₁ to C₁₀ alkyl, preferably from ethyl, propyl, butyl, pentyl and hexyl, most preferably from propyl, butyl, or pentyl.
R^{S12}, R^{S22} are independetly selected from H and a C₁ to C₄ alkyl, preferably H, methyl or ethyl.

For etching SiGe against Si, most preferably the (first) selectivity enhancer may be a compound of formula S4

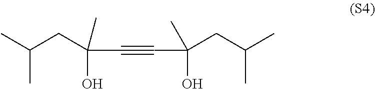 [SMILES: CC(C)CC(C)(O)C#CC(C)(O)CC(C)C]

available from Evonik under the trade name Surfynol® 104.

For etching SiGe having a higher Ge content against SiGe having a lower Ge content, most preferably the (first) selectivity enhancer may be a compound of formula S5

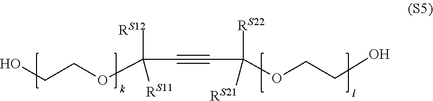

wherein
R^{S11}, R^{S21} are indenpendetly selected from a C₁ to C₁₀ alkyl, preferably from ethyl, propyl, butyl, pentyl and hexyl, most preferably from propyl, butyl, or pentyl.
R^{S12}, R^{S22} are independetly selected from H and a C₁ to C₄ alkyl, preferably H, methyl or ethyl
k, l are integers independently selected from 1 to 30, prefarbly from 1 to 20, most preferably from 1 to 15. Advantageously the sum of k and l is about 5 to 20 or about 20 to 40.

Such compounds are available from Evonik under the trade names Surfynol® 465 and Surfynol® 485 W.

The selectivity enhancer of the first preferred embodiment may be present in an amount of from about 0.0005 to about 0.03% by weight, preferably of from about 0.001 to about 0.02% by weight, most preferably of from about 0.005 to about 0.015% by weight. A single selectivity enhancer may increase the SiGe/Si selectivity up to more than 500, preferably more than 750, most preferably more than 1000. A single selectivity enhancer may also increase the SiGe/SiGe selectivity up to more than 10, preferably more than 20, most preferably more than 50.

In a second preferred embodiment, R^{S1} may be Y^{S}—(CO)—OH, wherein Y^{S1} may be a chemical bond or the same as X^{S} described above.

Preferably the (first) selectivity enhancer may be a compound of formula S3

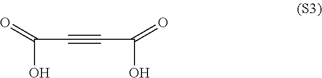

The selectivity enhancer of the second preferred embodiment may be present in an amount of from about 0.1 to about 3% by weight, preferably of from about 0.5 to about 2% by weight.

The composition according to the invention may comprise one or more of the selectivity enhancers described herein.

A particularly preferred composition comprises one single selectivity enhancer of the first preferred embodiment, particularly one single selectivity enhancer of formula S2 or formula S4.

Another particularly preferred composition comprises a first selectivity enhancer of the first preferred embodiment, particularly a first selectivity enhancer of formula S2 or formula S4; and further comprises a second selectivity enhancer of the second preferred embodiment, particularly a second selectivity enhancer of formula S3. If a first selectivity enhancer of formula S2 or formula S4 and a second selectivity enhancer of formula S3 are used the weight ratio of first and the second selectivity enhancer preferably is from 0.0001 to 0.1, most preferably from 0.001 to 0.02. The combination of a first and a second selectivity enhancer may increase the SiGe/Si selectivity up to more than 104.

### Additional SiGe Selectivity Enhancer

The composition comprises a silane as additional SiGe selectivity enhancer. The silane further increases the SiGe selectivity over the silicon containing layer, particularly the SiGe/SiOₓ, SiGe/SiON or SiGe/SiN selectivity. It also has the function of a hardmask protecting agent that significantly improves the hardmask compatibility of the SiGe etching composition.

In a first embodiment monomeric silanes of formula S41 may be used:

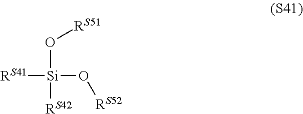

wherein
R^{S41} is C₁ to C₆ alkyl which may be unsubstituted or substituted by by —NR^{S61}R^{S62} or —OR^{S61};
R^{S42}, R^{S43} are independently selected from C₁ to C₆ alkoxy and C₁ to C₆ alkyl which may be unsubstituted or substituted by —NR^{S61}R^{S62} or —OR^{S61};
R^{S51}, R^{S52} are independently selected from C₁ to C₆ alkyl which may be unsubstituted or substituted by —NR^{S61}R^{S62} or —OR^{S61}.

In a preferred embodiment R^{S41} is C₁ to C₅ alkyl, preferably C₁ to C₄ alkyl, even more preferably methyl, ethyl or propyl, most preferably methyl or ethyl.

In a first preferred alternative R^{S42} is C₁ to C₅ alkyl, preferably C₁ to C₄ alkyl, even more preferably methyl, ethyl or propyl, most preferably methyl or ethyl. In a second preferred alternative R^{S42} is C₁ to C₅ alkoxy, preferably C₁ to C₄ alkoxy, even more preferably methoxy, ethoxy or propoxy, most preferably methoxy or ethoxy.

In a preferred embodiment R^{S51} and R^{S52} are independently C₁ to C₅ alkyl, preferably C₁ to C₄ alkyl, even more preferably methyl, ethyl or propyl, most preferably methyl or ethyl.

All substituents R^{S41}, R^{S42}, R_{S51}, and R^{S52} may be unsubstituted or substituted by one or more —NR^{S61}R^{S62} or OR^{S61}, preferably unsubstituted or substituted by one or more —NH₂, —NHR^{S71}, and —NHR^{S7}1R^{S72}, wherein R^{S71} and R^{S71} are independently methyl, ethyl, propyl or butyl. Most preferably all substituents R^{S41}, R^{S42}, R^{S511}, and R^{S522} are unsubstituted.

In a preferred embodiment silanes of formula S49 may be used:

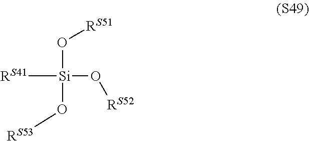

wherein
R^{S51}, R^{S52}, R^{S53} are independently selected from methyl, ethyl, propyl and butyl, preferably methyl and ethyl; R^{S41} is selected from methyl, ethyl, propyl and butyl, preferably methyl and ethyl.

All substituents R^{S41}, R^{S51}, R^{S52}, and R^{S53} may be unsubstituted or substituted by one or more —NR^{S6}1R^{S62} or OR^{S61}, preferably unsubstituted or substituted by one or more —NH₂, —NHR^{S71}, and —NHR^{S71}R^{S72}, wherein R^{S71} and R^{S71} are independently methyl, ethyl, propyl or butyl. Most preferably all substituents R^{S41}, R^{S51}, R^{S52}, and R^{S53} are unsubstituted

Particularly preferred is methyltrimethoxysilane

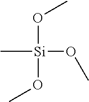

In a second embodiment the composition comprises derivatives of the monomeric silanes described above that are obtainable by homocondensation of the compounds of formula S41 or by co-condensation of the compounds of formula S41 with silanes of formula S42 in a weight ratio of 0.1 or more, preferably 0.2 or more, even more preferably 0.3 or more, most preferably 0.5 or more

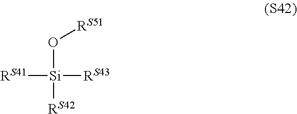

Such silane condensation products may also form when using the monomeric silanes of formula 41 described above. Usually, due to the low concentrations used in the composition, low average degrees of polymerization of up to about 10, preferably up to about 5, most preferably up to about 3 are to be expected. To some extend the monomeric silanes may also hydrolyse to some extent when using the aqueous etching compositions.

One type of homocondensates are the linear silanes of formula S43:

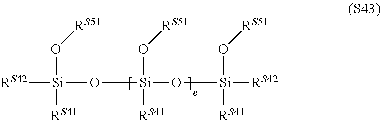

wherein e is an integer from 0 to 5, preferably 0, 1 or 2, most preferably 1;
or co-condensates of formula S44

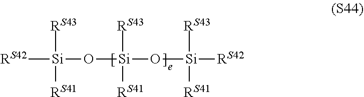

wherein
e is an integer from 0 to 5, preferably 0, 1 or 2, most preferably 1, and wherein at least one, preferably two of R^{S43} are —O—R^{S51}.

Substituent R^{S43} may be unsubstituted or substituted by one or more —NR^{S61}R^{S62} or OR^{S61} preferably unsubstituted or substituted by one or more —NH₂, —NHR^{S61}, and, most preferably unsubstituted.

Another type of homocondensates are the branched silanes of formula S45:

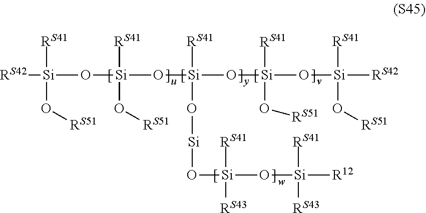

wherein
u, v, w are integers independently selected from 0 to 5, preferably 0, 1, 2 or 3, most preferably 0 or 1,
y is an integer from 1 to 5, preferably 1 or 2, most preferably 1;
or co-condensates of formula S46

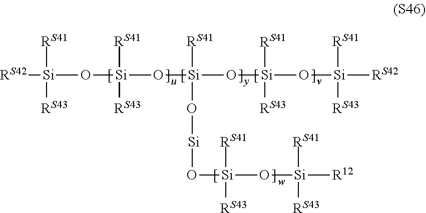

wherein
u, v, w are integers independently selected from 0 to 5, preferably 0, 1, 2 or 3, most preferably 0 or 1,
y is an integer from 1 to 5, preferably 1 or 2, most preferably 1; and at least one, preferably two of R^{S43} are —O—R^{S51}.

Yet another type of homocondensates are cyclic silanes of formula S47:

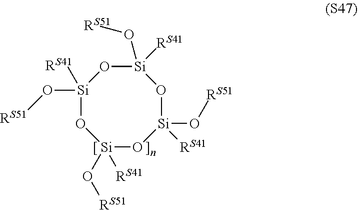

wherein n is 0, 1 or 2, preferably 0 or 1, most preferably 1;
or co-condensates of formula S48

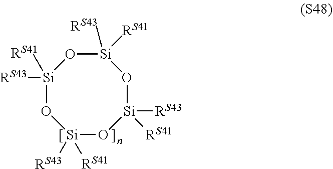

The concentration of the silanes of formulae S41 to S48 may generally be in the range of about 0.001 to about 3% by weight, preferably of from about 0.005 to about 2% by weight, even more preferably from about 0.05 to about 1% by weight, most preferably from about 0.1 to about 0.5% by weight, based on the total weight of the composition.

There may be one or more silanes in the composition, however it is preferred to use only one additive of formulae S41 to S48.

### Acid

The etching composition according to the invention may further comprise an acid. Such acid may be an inorganic acid, an organic acid, or a combination thereof. Preferably the acid is an organic acid or a combination of an inorganic acid and an organic acid.

Typical inorganic acids may be selected from but are not limited to sulfuric acid or phosphoric acid. Preferably, the inorganic acid comprises or consists of a strong inorganic acid, particularly sulfuric acid.

Typical organic acids may be selected from but are not limited to C₁ to C₁₀ mono, di or tri carboxylic acids, sulfonic acids, phosphonic acids, and the like. Preferred are C₁ to C₁₀ mono, di or tri carboxylic acids.

In a preferred embodiment, the acid comprises or consists of a hydroxy carboxylic acid, particularly but not limited to citric acid or tartaric acid. In another preferred embodiment the acetylenic compound, such as but not limited to acetylene dicarboxylic acid, also has acidic properties and therefore no further acid is required. Particularly preferred are acetic acid, phosphoric acid and tartaric acid.

If present, the acid may be used in the etching composition in an amount of from about 0.1% to about 5% by weight, more preferably of from about 0.2% to about 4% by weight, even more preferably of from about 0.3% to about 3% by weight most prefereably of from about 0.5 to about 2% by weight.

### Organic Solvents

Even not preferred, the etching composition may optionally comprise one or more organic solvents.

In individual cases, a composition according to the invention as defined herein may further comprise as an optional additional component: One or more water-miscible organic solvents, preferably selected from the group consisting of tetrahydrofuran (THF), N-methylpyrrolidone (NMP), di-methyl formamide (DMF), dimethyl sulfoxide (DMSO), ethanol, isopropanol, butyldiglycol, butylglycol, sulfolane (2,3,4,5-tetrahydrothiophene-1,1-dioxide) and mixtures thereof; more preferably selected from the group consisting of THF, NMP, DMF, DMSO, sulfolane and mixtures thereof.

The term “water-miscible organic solvent” in the context of the present invention preferably means that an organic solvent fulfilling this requirement is miscible with water at least in a 1:1 (w/w) ratio at 20° C. and ambient pressure. Preferably the or at least one water-miscible organic solvent (H) is sulfolane. Particularly, preferred are compositions according to the present invention which do not comprise one or more water-miscible organic solvents.

In individual cases, a composition according to the invention as defined herein (or a composition according to the invention as described above or below as being preferred) is preferred wherein the total amount of the one or more water-miscible organic solvents, (i.e. the solvent component) present in an amount of from about 0.1 to about 30% by weight, preferably of from about 0.5 to about 10% by weight, more preferably of from about 1 to about 7.5% by weight, even more preferably of from about 1 to about 6% by weight, based on the total weight of the composition.

Most preferably the etching composition is an aqueous solution that is essentially free of organic solvents. Essentially free herein means that the content of organic solvents is below 1% by weight, preferably below 0.1% by weight, even more preferably below 0.01% by weight, most preferably below the detection limit.

### Surfactants

The composition may also further comprise one or more surfactants.

Preferred surfactants are selected from the group consisting of
(i) anionic surfactants, preferably selected from the group consisting of ammonium lauryl sulfate, fluorosurfactants, preferably selected from the group consisting of perfluorinated alkylsulfonamide salts (preferably perfluorinated, N-substituted alkylsulfonamide ammonium salts, PNAAS), perfluorooctanesulfonate, perfluorobutanesulfonate, perfluorononanoate and perfluorooctanoate; alkyl-aryl ether phosphates and alkyl ether phosphates;
(ii) zwitterionic surfactants, preferably selected from the group consisting of (3-[(3-cholamidopropyl)dimethylammonio]-1-propanesulfonate) (“CHAPS”), cocamidopropyl hydroxysultaine (CAS RN 68139-30-0), {[3-(dodecanoylamino)propyl](dimethyl)-ammonio}acetate, phosphatidylserine, phosphatidylethanolamine, phosphatidylcholine; and
(iii) non-ionic surfactants, preferably selected from the group consisting of glucoside alkyl ethers, glycerol alkyl ethers, cocamide ethanolamines and lauryldimethylaminoxide.

More preferred surfactants in compositions according to the invention are or comprise perfluorinated, N-substituted alkylsulfonamide ammonium salts. Preferred surfactants (E) in compositions according to the invention do not comprise metals or metal ions.

Particular preferred surfactants are those of formula F1

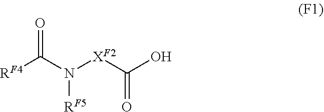

wherein
X^{F2} is a C₁ to C₄ alkanediyl;
R^{F4} is a C₁₂ to C₃₀ alkyl or a C₁₂ to C₃₀ alkenyl; and
R^{F5} is a C₁ to C₄ alkyl.

A composition according to the invention as defined herein is also preferred wherein the amount of the one or more surfactants of the surfactant present is of from about 0.0001 to about 1% by weight, preferably of from about 0.0005 to about 0.5% by weight, more preferably in an amount of from about 0.001 to about 0.01% by weight, based on the total weight of the composition.

### Chelating Agents

The etching composition may optionally comprise one or more chelating agents.

Preferred chelating agents are of 1,2-cyclohexylenedinitrilotetraacetic acid, 1,1,1,5,5,5-hexafluoro-2,4-pentane-dione, acetylacetonate, 2,2′-azanediyldiacetic acid, ethylenediamine-tetra-acetic acid, etidronic acid, methanesulfonic acid, acetylacetone, 1,1,1-trifluoro-2,4-pentanedione, 1,4-benzoquinone, 8-hydroxyquinoline, salicyli-dene aniline; tetrachloro-1,4-benzoquinone, 2-(2-hydroxyphenyl)-benzoxazol, 2-(2-hydroxyphenyl)-benzothiazole, hydroxyquinoline sulfonic acid, sulfosali-cylic acid, salicylic acid, pyridine, 2-ethylpyridine, 2-methoxypyridine, 3-methoxypyridine, 2-picoline, dimethylpyridine, piperidine, piperazine, tri-ethylamine, triethanolamine, ethylamine, methylamine, isobutylamine, tert-butylamine, tributylamine, dipropylamine, dimethylamine, diglycol amine, monoethanolamine, methyldiethanolamine, pyrrole, isoxazole, bipyridine, py-rimidine, pyrazine, pyridazine, quinoline, isoquinoline, indole, 1-methylimidazole, diisopropylamine, diisobutylamine, aniline, pentamethyldi-ethylenetriamine, acetoacetamide, ammonium carbamate, ammonium pyr-rolidinedithiocarbamate, dimethyl malonate, methyl acetoacetate, N-methyl acetoacetamide, tetramethylammonium thiobenzoate, 2,2,6,6-tetramethyl-3,5-heptanedione, tetramethylthiuram disulfide, lactic acid, ammonium lactate, formic acid, propionic acid, gamma-butyrolactone, and mixtures thereof;

In a preferred embodiment the chelating agent may be Diethylenetriaminepentaacetic acid (DTPA) or may comprise DTPA as well as one or more of the other chelating agents above. Compositions comprising DTPA as chelating agent have shown particularly low etch rates for silicon oxide.

A composition according to the invention as defined herein is also preferred wherein the amount of the one or more chelating agents present is of from about 0.005 to about 2% by weight, preferably of from about 0.01 to about 1% by weight, more preferably of from about 0.02 to about 0.2% by weight, based on the total weight of the composition.

### Composition

In a preferred embodiment the pH of the etching composition is from 4 to 8, particularly from 5 to 7. If the pH is too low, the silicon oxide etch rate is too high, if the pH is too high, the Si etch rate is too high. The pH of the bath may be adjusted by a pH adjustor, particularly ammonia.

A composition according to the invention as defined herein is specifically preferred wherein the composition consists of hydrogen peroxide, ammonium fluoride, a first selectivity enhancer of formula S2 or S4, optionally a second selectivity enhancer of formula S3, an additional selectivity enhancer of formula S41, optionally an acid, optionally a pH adjustor, and water, as defined herein and to be defined based on the examples.

A composition according to the invention as defined herein is specifically preferred wherein the composition consists of hydrogen peroxide, ammonium fluoride, a first selectivity enhancer of formula S3, optionally a surfactant of formula S4, an additional selectivity enhancer of formula S41, optionally an acid, optionally a pH adjustor, and water, as defined herein and to be defined based on the examples.

A composition is particularly preferred wherein the composition comprises or consists of
(a) one or more oxidizing agents, selected from a peroxide, and preferably the one or more oxidizing agent consist of or comprise hydrogen peroxide, in an amount of from about 1 to about 2% by weight, more preferably from about 2 to about 12% by weight, even more preferably from about 3 to about 7% by weight, most preferably of from about 4 to about 6% by weight;
(b) one or more etchants comprising a source of fluoride ions, selected from the group consisting of ammonium fluoride, ammonium bifluoride, triethanolammonium fluoride, diglycolammonium fluoride, methyldiethanolammonium fluoride, tetramethylammonium fluoride, triethylamine trihydrofluoride, hydrogen fluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, tetrabutylammonium tetrafluoroborate and mixtures thereof, and preferably consists of or comprises ammonium fluoride, hydrogen fluoride or a combination thereof, in an amount of from about 0.1 to about 14% by weight, preferably of from about 1 to about 12% by weight, more preferably of from about 3 to about 10% by weight, even more preferably of from about 4 to about 10% by weight, most preferably of from about 6 to about 8% by weight;
(c) a first selectivity enhancer of formula S1, particularly of formula S2, S3, or S4 in an amount of from about 0.0005 to about 0.02% by weight, preferably of from about 0.005 to about 0.015% by weight;
(d) if the first selectivity enhancer is not a compound of formula S3, optionally a second selectivity enhancer of formula S3 in an amount of from about 0.1 to about 3% by weight, preferably of from about 0.5 to about 2% by weight;
(e) an additional selectivity enhancer of formula S41 in an amount of from 0.01 to 5% by weight, preferably of from 0.1 to 1% by weight or derivatives thereof obtainable by homocondensation of the compounds of formula S41 or by co-condensation of the compounds of formula S41 with silanes of formula S42 in a weight ratio of 0.1 or more;
(f) one or more acids selected from an inorganic acid and an organic acid, preferably an organic acid, more preferably a C₁ to C₁₀ mono, di or tri carboxylic acid, even more preferably a hydroxycarboxylic acid, even more prefarably a dihydroxydicarboxylic acid, most preferably tartaric acid, or a combination thereof, and preferably consists of or comprises tartaric acid in an amount of from about 0.1% to about 5% by weight, more preferably of from about 0.2% to about 4% by weight, even more preferably of from 0.3% to 3% by weight most preferably of from 0.5 to 2% by weight;
(g) optionally one or more surfactants selected from the group consisting of (i) anionic sur-factants, preferably selected from the group consisting of ammonium lauryl sulfate, fluorosurfactants, preferably selected from the group consisting of perfluorinated alkylsulfon-amide salts (preferably perfluorinated, N-substituted alkylsulfonamide ammonium salts), perfluorooctanesulfonate, perfluorobutanesulfonate, perfluorononanoate and perfluorooctanoate; alkyl-aryl ether phosphates and alkyl ether phosphates, (ii) zwitterionic surfac-tants, preferably selected from the group consisting of (3-[(3-cholamidopropyl)dimethyl-ammonio]-1-propanesulfonate), cocamidopropyl hydroxysultaine, {[3-(dodecanoylamino)propyl]-(dimethyl)ammonio}acetate, phosphatidylserine, phosphatidylethanolamine, phosphatidylcholine, (iii) non-ionic surfactants, preferably selected from the group consisting of glucoside alkyl ethers, glycerol alkyl ethers, cocamide ethanolamines and lauryldime-thylaminoxide; and preferably the one or more surfactants are or comprise a compound of formula F1, in an amount of from about 0.0005 to about 0.5% by weight, more preferably in an amount of from about 0.001 to about 0.01% by weight;
(h) optionally one or more chelating agents selected from the group consisting of diethylenetriaminepentaacetic acid, 1,2-cyclohexylenedinitrilotetraacetic acid, 1,1,1,5,5,5-hexafluoro-2,4-pentane-dione, acetylacetonate, 2,2′-azanediyldiacetic acid, ethylenediamine-tetra-acetic acid, etidronic acid, methanesulfonic acid, acetylacetone, 1,1,1-trifluoro-2,4-pentanedione, 1,4-benzoquinone, 8-hydroxyquinoline, salicyli-dene aniline; tetrachloro-1,4-benzoquinone, 2-(2-hydroxyphenyl)-benzoxazol, 2-(2-hydroxyphenyl)-benzothiazole, hydroxyquinoline sulfonic acid, sulfosalicylic acid, salicylic acid, pyridine, 2-ethylpyridine, 2-methoxypyridine, 3-methoxypyridine, 2-picoline, dimethylpyridine, piperidine, piperazine, tri-ethylamine, triethanolamine, ethylamine, methylamine, isobutylamine, tert-butylamine, tributylamine, dipropylamine, dimethylamine, diglycol amine, monoethanolamine, methyl-diethanolamine, pyrrole, isoxazole, bipyridine, py-rimidine, pyrazine, pyridazine, quinoline, isoquinoline, indole, 1-methylimidazole, diisopropylamine, diisobutylamine, aniline, penta-methyldiethylenetriamine, acetoacetamide, ammonium carbamate, ammonium pyrrolidine-dithiocarbamate, dimethyl malonate, methyl acetoacetate, N-methyl acetoacetamide, tetra-methylammonium thiobenzoate, 2,2,6,6-tetramethyl-3,5-heptanedione, tetramethylthiuram disulfide, lactic acid, ammonium lactate, formic acid, propionic acid, gamma-butyrolactone, and mixtures there-of, and preferably is or comprises 1,2-cyclohexylenedinitrilotetraacetic acid, in an amount of from about 0.005 to about 2 wt %, preferably in a total amount of from about 0.01 to about 1 wt %, more preferably in a total amount of from about 0.02 to about 0.2 wt %, based on the total weight of the composition;
(k) water as balance to a total of 100 wt.-% of the composition in each case; and
(l) optionally one or more water-miscible organic solvents, preferably selected from the group consisting of tetrahydrofuran (THF), N-methylpyrrolidone (NMP), di-methyl formamide (DMF), dimethyl sulfoxide (DMSO) and sulfolane (2,3,4,5-tetrahydrothiophene-1,1-dioxide) and mixtures thereof, in an amount of from about 0.1 to about 30 wt %, preferably of from about 0.5 to about 10 wt %, more preferably of from about 1 to about 7.5 wt %, even more preferably of from about 1 to about 6 wt %;
all based on the total weight of the composition, wherein the pH of the composition is of from about 4 to about 8, preferably of from about 5 to about 7, and wherein the % amounts of the components add to 100% by weight in each case.

### Application

In a first embodiment the composition is particularly useful for selectively etching a layer comprising a silicon germanium alloy (SiGe) in the presence of a silicon layer, in particular crystalline Si and preferably in the presence of silicon oxide.

In a second embodiment the composition is particularly useful for selectively etching a silicon germanium alloy having a first germanium content in the presence of silicon germanium alloy having a second germanium content, wherein the first germanium content is higher than the second germanium content, preferably in the presence of silicon oxide.

In the second embodiment, the first germanium content is at least 5% by weight, preferably 10% by weight, more preferably 15% by weight, most preferably preferably 20% by weight higher than the second germanium content. It is particularly preferred to etch SiGe40 over SiGe20.

It will be appreciated that it is common practice to make concentrated forms of the compositions to be diluted prior to use. For example, the compositions may be manufactured in a more concentrated form and thereafter diluted with water, at least one oxidizing agent, or other components at the manufacturer, before use, and/or during use. Dilution ratios may be in a range from about 0.1 parts diluent to 1 parts composition concentrate to about 100 parts diluent to 1 part composition concentrate.

Accordingly, one embodiment relates to a kit including, in one or more containers, one or more components adapted to form the compositions described herein. Preferably, one container comprises the at least one oxidizing agent and a second container comprises the remaining components, e.g., at least one etchant, at least selectivity enhancer, water, and optionally other components described herein, for combining at the fab or the point of use.

In the use of the compositions described herein, the composition typically is contacted with the device structure for a sufficient time of from about 3 minutes to about 60 minutes, preferably about 5 minutes to about 20 minutes in a batch process and about 20 seconds to about 5 minutes, preferably about 30 seconds to about 3 minutes in a single wafer process.

In the use of the compositions described herein, the composition typically is contacted with the device structure at temperature in a range of from about 10° C. to about 80° C., preferably about 20° C. to about 60° C. Such contacting times and temperatures are illustrative, and any other suitable time and temperature conditions may be employed that are efficacious to achieve the required removal selectivity. One advantage of the composition according to the present invention is its low temperature dependence of the SiGe/Si etch ratio. Particularly the SiGe etch rate and the SiGe/Si etch ratio is still very high at temperatures below 30° C. so that the substrates may be processed at room temperature.

Following the achievement of the desired etching action, the composition can be readily removed from the microelectronic device to which it has previously been applied, e.g., by rinse, wash, or other removal step(s), as may be desired and efficacious in a given end use application of the compositions of the present invention. For example, the device may be rinsed with a rinse solution including deionized water, an organic solvent, and/or dried (e.g., spin-dry, N₂, vapor-dry etc.).

It may be useful to clean the blanket wafer surfaces for approx 30 s with an aqueous solution containing 0.1% to 1% by weight HF at room temperature, then dipped into UPW for 2-3 s and dried with compressed air. However, by using the composition according to the present invention, it is possible and preferred to omit such pretrament with HF.

The etching composition described herein may be advantagoulsy used for selectively etching a layer comprising SiGe in the presence of a layer comprising or consisting of Si and in the presence of a layer comprising or consisting of silicon oxide.

The etching composition described herein may be advantagoulsy used in a process of selectively removing a layer comprising or consisting of a silicon germanium alloy from a surface of a microelectronic device relative to a layer comprising or consisting of Si and a layer comprising or consisting of silicon oxide, the process comprising:
(a) providing a microelectronic device surface that includes the layer comprising the silicon germanium alloy and the layer comprising or consisting of Si and a layer comprising or consisting of silicon oxide,
(b) providing a composition as described above, and
(c) contacting the surface with the composition for a time and at a temperature effective to selectively remove the layer comprising silicon-germanium relative to the layer comprising or consisting of Si and the layer comprising or consisting of silicon oxide.

Preferably the SiGe etch rates of the compositions according to the invention are 200 A/min or more, more preferably 300 A/min or more. Preferably the Si etch rates of the compositions according to the invention are 2 A/min or below, more preferably 1 A/min or below. Preferably the etch rates of SiOₓ, SiN and SiON with the compositions according to the invention are 2 A/min or below, more preferably 1 A/min or below. Preferably the etch rate of the layer comprising silicon-germanium is at least 200, preferably at least 500, more preferably at least 750, even more preferably at least 1000, even more preferably preferably at least 2000, most preferably more than 5000 times faster than the etch rate of the silicon layer (SiGe/Si selectivity).

The etching composition described herein may be advantagoulsy used in a process for the manufacture of a semiconductor device, comprising the step of selectively removing silicon-germanium from a surface of a microelectronic device relative to a material comprising or consisting of Si and a meterial comrising or consisting of silicon oxide.

All percent, ppm or comparable amounts refer to the weight with respect to the total weight of the respective composition except where otherwise indicated. All cited documents are incorporated herein by reference.

The following examples shall further illustrate the present invention without restricting the scope of this invention.

### EXAMPLES

The following substrates were used in examples 1-3: SALSA Ill by IMEC as schematically shown in FIG. 1. The substrate comprised several stacked SiGe and Si layers. SALSA 3 layer build up from top to bottom: SiO₂ (50 nm)—SiN (50 nm)—SiO₂ (5 nm)—Si (25 nm)—SiGe (25 nm) Si (20 nm)—SiGe (20 nm)—Si (15 nm)—SiGe (15 nm)—Si (10 nm)—SiGe (10 nm)—Si (5 nm)—SiGe (5 nm)—Si<100> Wafer (ca. 0.70 mm). All SiGe layer contained 25% by weight of Germanium. The Si layers consisted of crystalline Si.

The following substrates were used in example 4 and 5: SALSA Ill by IMEC. The substrate comprised several stacked SiGe and Si layers. SALSA 3 layer build up from top to bottom: SiO₂ (50 nm)—SiN (50 nm)—Si_{0.8}Ge_{0.2} (10 nm)—Si_{0.8}Ge_{0.4} (15 nm)—Si_{0.3}Ge_{0.2} (10 nm)—Si_{0.6}Ge_{0.4} (7 nm)—Si_{0.3}Ge_{0.2} (10 nm)—Si<100> Wafer (ca. 0.70 mm).

The following materials were used in electronic grade purity:
H₂O₂(31%)
NH₄F
Aqueous NH₃
Methyltrimethoxysilane
citric acid
phosphoric acid
acetic Acid
Surfynol® 104 (available from Evonik)

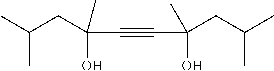 [SMILES: CC(C)CC(C)(O)C#CC(C)(O)CC(C)C]

Surfynol® 465 (available from Evonik, k, l=10)
Surfynol® 485 W (available from Evonik, k, l=30)

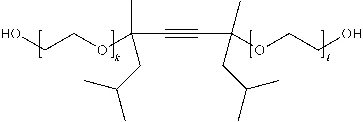

All amounts given for the compounds in the compositions are absolute amounts, i.e. excluding water, in the overall mixture.

### Etch Bath Preparation:

The etching bath vessel was set to a temperature of 24° C.+/−0.5° C. The pH was adjusted to 6.05 with NH₃

### Optional Pre-Etching:

Before etching some of the coupons containing the microstructures were treated for 60 s with 0.5% HF.

### Etching:

After rinsing with ultra pure water (UPW, electronic grade), the coupons were insert into the etch bath for 60 seconds. After etching, the coupons were rinsed with UPW and dried with compressed air.

### Example 1

The compositions listed in table 1a were prepared.

TABLE 1a

| | Comp. Ex 1.1 | Ex 1.2 | Ex. 1.3 |
|---|---|---|---|
| | composition | composition | composition |
| NH₄F | 14.0 wt % | 14.0 wt % | 7.0 wt % |
| H₂O₂ | 10.0 wt % | 7.5 wt % | 7.5 wt % |
| Surfynol ® 104 | 0.005 wt % | 0.005 wt % | 0.005 wt % |
| citric acid | 1.00 wt % | | |
| phosphoric acid | | 0.5 wt % | |
| acetic acid | | | 1.0 wt % |
| Methyltrimethoxysilane | | 0.3 wt % | 0.3 wt % |
| NH₃ | | | 0.17 wt % |
| Water | 75.0 wt % | 77.7 wt % | 84.0 wt % |

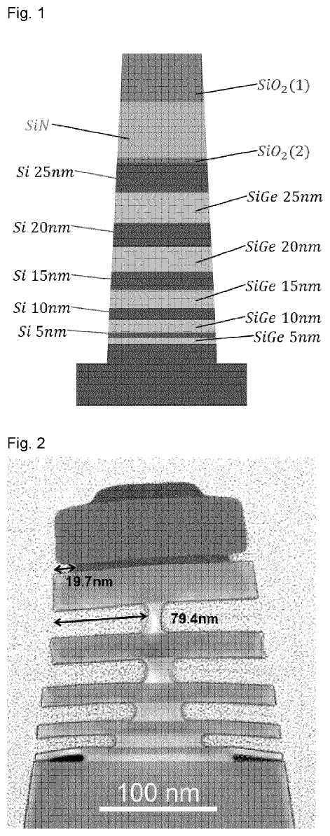

The etching rates in A/min were determined by TEM according to the lateral etching depth of the top SiGe25 and Si layers. The results are depicted in table 1b and the substrate etched with the compositions according to examples 1.1, 1.2 and 1.3 are shown in FIGS. 2, 3 and 4, respectively. FIG. 6 shows the substrate after treatment under the conditions of example 1.2 without HF pretreatment.

TABLE 1b

| | Comp. Ex 1.1 | Ex 1.2 | Ex 1.3 |
|---|---|---|---|
| Si | 0 Å/min | 0 Å/min | 0 Å/min |
| SiGe(25%) | 794 Å/min | 667 Å/min | 667 Å/min |
| SiO₂ | 197 Å/min | 0 Å/min | 0 Å/min |
| SiN | 59 Å/min | 0 Å/min | 0 Å/min |

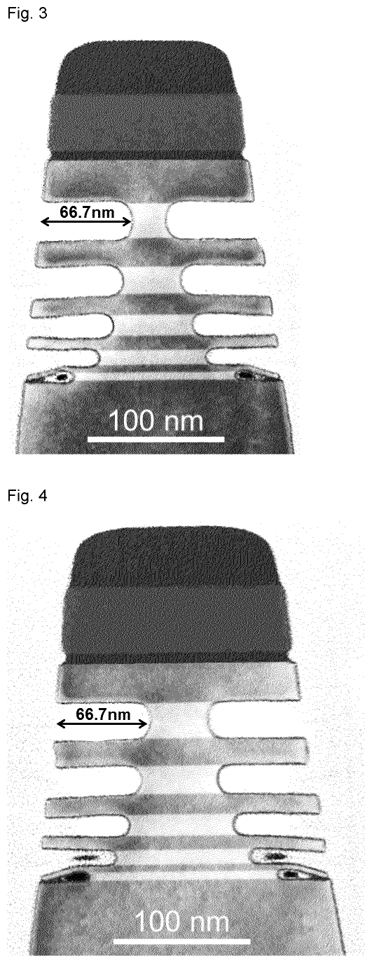

Table 1b and FIGS. 3 and 4 show that the lateral loss of SiO₂ is only caused by the pretreatment with HF in experiments 1.2 and 1.3. Furthermore, FIG. 6 shows that without HF pretreatment, there is no loss of SiOₓ or Si₃N₄.

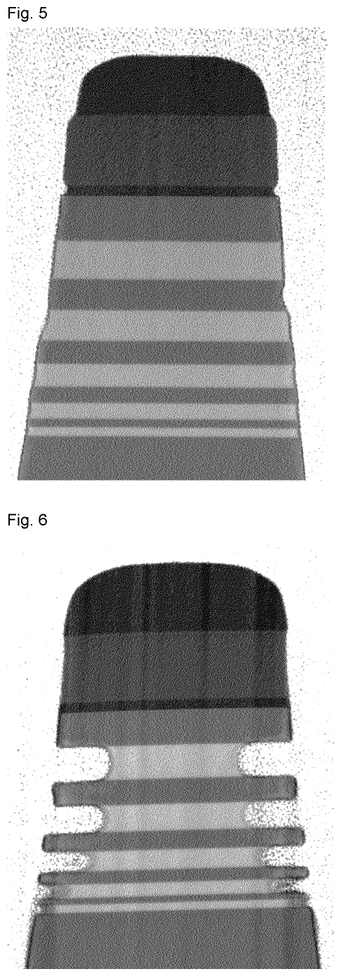

For comparison, FIG. 5 shows the result of a pretreatment with HF without any further etching. Even if the SiGe etch rate is lower, the overall selectivity of SiGe vs Si or SiOₓ is significantly increased.

### Example 2

Example 1 was repeated with the compositions listed in table 2a and the results are depicted in table 2b. The etching rates were determined by Ellipsometry by comparing the layer thickness before and after etching.

TABLE 2a

| | Ex 2.1 | Ex 2.2 | Ex. 2.3 | Ex 2.4 | Ex 2.5 | Ex. 2.6 |
|---|---|---|---|---|---|---|
| NH₄F | 7.0 wt % | 7.0 wt % | 7.0 wt % | 7.0 wt % | 7.0 wt % | 7.0 wt % |
| H₂O₂ | 10.0 wt % | 7.5 wt % | 7.5 wt % | 10.0 wt % | 7.5 wt % | 7.5 wt % |
| Surfynol® 104 | 0.005 wt % | 0.005 wt % | 0.005% | 0.005 wt % | 0.005 wt % | 0.005% |
| acetic acid | 1.00 wt % | | | | | |
| phosphoric acid | | 1.60 wt % | 1.30 wt % | 1.00 wt % | | |
| tartaric acid | | | | | 1.00 wt % | 1.25 wt % |
| Methyltrimethoxysilane | 0.3 wt % | 0.3 wt % | 0.3 wt % | 0.3 wt % | 0.3 wt % | 0.3 wt % |
| NH₃ | 0.24 wt % | 0.38 wt % | 0.28 wt % | 0.18 wt % | 0.17 wt % | 0.23 wt % |
| Water | 84.2 wt % | 83.6 wt % | 83.9 wt % | 84.2 wt % | 84.2 wt % | 83.9 wt % |

TABLE 2b

| | Ex 2.1 | Ex 2.2 | Ex. 2.3 | Ex 2.4 | Ex 2.5 | Ex. 2.6 |
|---|---|---|---|---|---|---|
| Si | 1 Å/min | 1 Å/min | 1 Å/min | 1 Å/min | 1 Å/min | 1 Å/min |
| SiO₂ | 1 Å/min | 2 Å/min | 0 Å/min | 1 Å/min | 0 Å/min | 0 Å/min |
| SiN | 0 Å/min | 0 Å/min | 0 Å/min | 1 Å/min | 2 Å/min | 1 Å/min |
| SiGe(25%) | 138 Å/min | 130 Å/min | 162 Å/min | 172 Å/min | 178 Å/min | 156 Å/min |

### Example 3

Example 1 was repeated with the compositions listed in table 3a and the results are depicted in table 3b. The etching rates were determined by Ellipsometry by comparing the layer thickness before and after etching.

TABLE 3a

| | Comp. | | | |
|---|---|---|---|---|
| | Ex 3.1 | Ex 3.2 | Ex 3.3 | Ex 3.4 |
| NH4F | 14.0 wt % | 14.0 wt % | 7.0 wt % | 7.0 wt % |
| H₂O₂ | 7.5 wt % | 7.5 wt % | 7.5 wt % | 7.5 wt % |
| Surfynol ® 104 | 0.005 wt % | 0.005 wt % | 0.005 wt % | 0.005 wt % |
| acetic acid | | | | 1.0 wt |
| phosphoric acid | 0.3 wt % | 0.3 wt % | 0.3 wt % | |
| Methyltrimethoxysilane | | 0.3 wt % | 0.3 wt % | 0.3 wt % |
| NH₃ | | | | 0.4 wt % |
| Water | 78.2 wt % | 77.9 wt % | 84.9 wt % | 83.8 wt % |

TABLE 3b

| | Comp. | | | |
|---|---|---|---|---|
| | Ex 3.1 | Ex 3.2 | Ex 3.3 | Ex 3.4 |
| Si | 0 Å/min | 0 Å/min | 0 Å/min | 0 Å/min |
| SiOₓ | 224 Å/min | 4 Å/min | 3 Å/min | 40 Å/min |
| SiN | 58 Å/min | 0 Å/min | 1 Å/min | 2 Å/min |
| SiGe(25%) | 489 Å/min | 319 Å/min | 277 Å/min | 307 Å/min |

A comparison of example 3.2 with comparative example 3.1 shows that the addition of methyltrimethoxysilane reduces the etch rates of Si, SiOₓ and SiN by more than one order of magnitude while only slightly reducing the SiGe etch rate. This leads to a strong selectivity of SiGe etching against Si, SiOₓ and SiN.

### Example 4

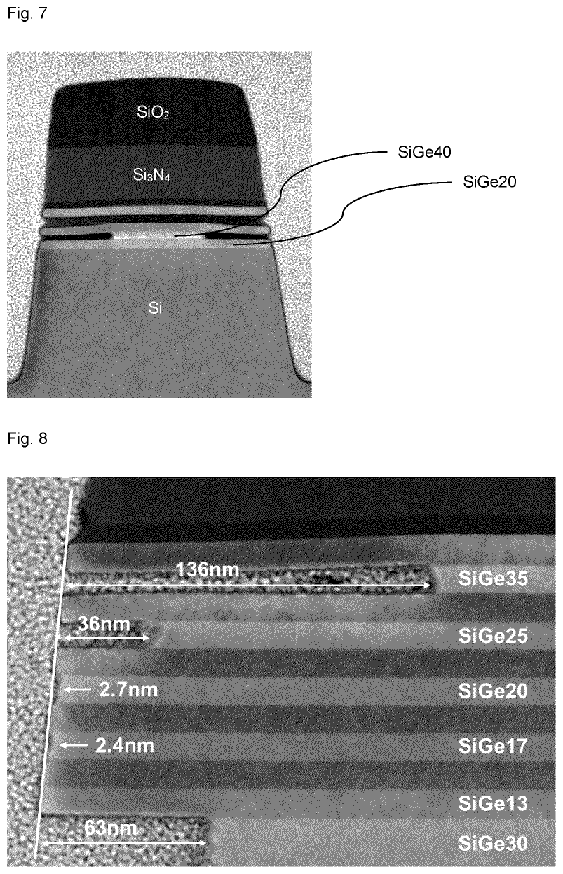

A composition comprising 7% NH₄F, 2.8% H₂O₂, 1.0% acetic acid, 0.17% NH₃, and 0.3% methyltrimethoxysilane was prepared and etched at 24° C. as decribed above. Etch rates for SiGe20, SiGe40 the SiGe40/SiGe20 selectivities, and the selectivity enhancer concentrations are depicted in table 4, respectively. The substrate etched with the compositions according to examples 4 with 50 ppm Surfynol® 104 is shown in FIG. 7.

TABLE 4

| | Surfynol ® 104 | | | Surfynol ® 465 | | | Surfynol ® 485 W | | |
|---|---|---|---|---|---|---|---|---|---|
| | SiGe20 | SiGe40 | | SiGe20 | SiGe40 | | SiGe20 | SiGe40 | |
| Conc. [ppm] | [A/min] | [A/min] | Sel. | [A/min] | [A/min] | Sel. | [A/min] | [A/min] | Sel. |
| 50 | 37 | 555 | 15 | — | — | — | 18 | 554 | 31 |
| 100 | 19 | 581 | 31 | 13 | 539 | 41 | 15 | 512 | 34 |
| 200 | 11 | 564 | 51 | 13 | 713 | 55 | 14 | 703 | 50 |
| 400 | — | — | — | 10 | 668 | 67 | 13 | 715 | 55 |

The alkynols significantly reduce the SiGe20 etch rates while the SiGe40 etch rates are still high. This results in a much higher selectrivity. Higher selectivities were observed throughout for the polyalkoxylated alkyne diols compared to the non-alkyoxylated ones. The results also show that SiGe40 could selectively be removed in the presence of SiGe20, Si, SiO₂, and Si₃N₄.

### Example 5

Example 4 was repeated for Surfynol® 465 at different H₂O₂ concentrations. The results are depicted in Table 5.

TABLE 5

| | 400 ppm Surfynol ® 465 | | |
|---|---|---|---|
| H₂O₂ conc. | SiGe20 | SiGe40 | |
| [wt.-%] | [A/min] | [A/min] | Sel. |
| 2.8 | 10 | 668 | 67 |
| 1.5 | 3 | 298 | 99 |
| 1.0 | 2 | 178 | 89 |

Table 5 shows that even higher selectivites were observed at lower H₂O₂ concentration.

### Example 6

The composition shown in Table 6 was prepared.

TABLE 6

| Compound | Conc. [wt %] |
|---|---|
| UPW Water | 88.9 |
| Acetic Acid | 1.30 |
| NH₃ | 0.17 |
| Trimethoxymethylsilane | 0.40 |
| Surfynol ® 104 | 0.007 |
| NH₄F | 9.20 |

This composition was mixed with mit H₂O₂ (31%) in a 90:1 ratio (VV) resulting in concentrations of 9.1 wt % NH₄F and 0.34 wt % H₂O₂. Etching experiments on were performed on a structured wafer comprising SiGe layers with different amounts of Ge. The results are shown in FIG. 8.

FIG. 8 shows that that SiGe may be slectrively etched up to SiGe25 against SiGe20.

1. A composition for selectively etching a first silicon germanium layer having a first germanium content in the presence of a silicon layer or a second silicon germanium layer having a second germanium content, wherein the first germanium content is higher than the second germanium content, the composition comprising:
(a) from 0.1 to 10% by weight of an oxidizing agent;
(b) from 1 to 20% by weight of an etchant comprising a source of fluoride ions;
(c) from 0.001 to 3% by weight of a selectivity enhancer of formula Si 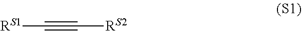
(d) from 0.001 to 3% by weight of an additional selectivity enhancer of formula S41 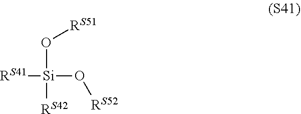
or derivatives thereof obtainable by homocondensation of the compounds of formula S41 or by co-condensation of the compounds of formula S41 with silanes of formula S42 in a weight ratio of 0.1 or more 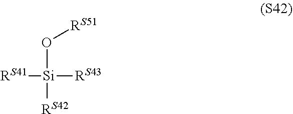
and
(e) water;
wherein
R^{S1} is selected from the group consisting of X^{S}—OH and Y^{S}—(CO)—OH;
R^{S2} is selected from the group consisting of (i) R^{S1}, (ii) H, (iii) C₁ to C₁₀ alkyl, (iv) C₁ to C₁₀ alkenyl, (v) C₁ to C₁₀ alkynyl, and (vi) —X^{S1}—(O—C₂H₃R^{S6})ₘ—OR^{S6};
R^{S6} is selected from the group consisting of H and C₁ to C₆ alkyl;
R^{S41} is C₁ to C₆ alkyl which may be unsubstituted or substituted by —NR^{S6}1R^{S62} or —OR^{S61};
R^{S42}, R^{S43} are independently selected from the group consisting of C₁ to C₆ alkoxy and C₁ to C₆ alkyl which both may be unsubstituted or substituted by —NR^{S61}R^{S62} or —OR^{S61};
R^{S51}, R^{S52} are independently selected from the group consisting of C₁ to C₆ alkyl which may be unsubstituted or substituted by —NR^{S6}1R^{S62} or —OR^{S61};
R^{S61}, R^{S62} are independently selected from the group consisting of H and C₁ to C₆ alkyl;
X^{S} is selected from the group consisting of a linear or branched C₁ to C₁₀ alkanediyl, a linear or branched C₂ to C₁₀ alkenediyl, a linear or branched C₂ to C₁₀ alkynediyl, and —X^{S1}—(O—C₂H₃R^{S6})ₘ—;
Y^{S} is selected from the group consisting of a chemical bond and X^{S};
X^{S1} is a C₁ to C₈ alkanediyl; and
m is an integer in a range of from 1 to 30.

2. The composition according to claim 1, wherein the oxidizing agent is a peroxide.

3. The composition according to claim 1, wherein the etchant is selected from the group consisting of hydrogen fluoride, ammonium fluoride, ammonium bifluoride, triethanolammonium fluoride, diglycolammonium fluoride, methyldiethanolammonium fluoride, tetramethylammonium fluoride, triethylamine tri-hydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, tetrabutylammonium tetrafluoroborate and mixtures thereof.

4. The composition according to claim 1, wherein the selectivity enhancer is present in an amount of
(a) from 0.0005 to 0.02% by weight if R^{S1} is X^{S}—OH, or
(b) from 0.1 to 3% by weight if R^{S1} is Y^{S}—(CO)—OH.

5. The composition according to claim 1, wherein R^{S1} is X^{S}—OH and X^{S} is a C₁ to C₈ alkanediyl.

6. The composition according to claim 5, wherein the selectivity enhancer is a compound of formula S2 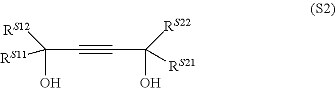
wherein
R^{S11}, R^{S21} are independently selected from the group consisting of a C₁ to C₆ alkyl, and
R^{S12}, R^{S22} are independently selected from the group consisting of H and a C₁ to C₁₀ alkyl.

7. The composition according to claim 1,
wherein R^{S1} is X^{S}—OH and X^{S} is
—X^{S1}—(O—C₂H₃R^{S6})ₘ—, wherein X^{S1} is a C₁ to C₈ alkanediyl.

8. The composition according to claim 7, wherein the selectivity enhancer is a compound of formula S5 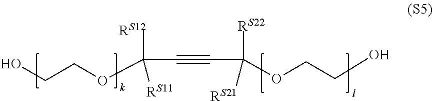
wherein
R^{S11}, R^{S21} are independently selected from the group consisting of a C₁ to C₆ alkyl,
R^{S12}, R^{S22} are independently selected from the group consisting of H and a C₁ to C₁₀ alkyl, and
k, l are integers independently selected from the group consisting of 1 to 30.

9. The composition according to claim 1, wherein the first selectivity enhancer is a compound of formula S3 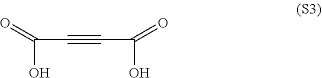
or, if the first selectivity enhancer is a compound of formula S2, the composition further comprises a second acetylenic compound of formula S3.

10. The composition according to claim 1, wherein
R^{S31}, R^{S32}, R^{S33} are independently selected from the group consisting of methyl, ethyl, propyl and butyl;
R^{S34}, R^{S35}, R^{S36} are independently H or selected from the group consisting of methyl, ethyl, propyl and butyl;
X^{S31} is selected from the group consisting of methanediyl, ethanediyl, propanediyl, butanediyl, and —X^{S1}—(O—C₂H₃R^{S6})ₘ—;
R^{S6} is H or selected from the group consisting of methyl and ethyl;
X^{S1} is selected from the group consisting of methanediyl, ethanediyl, propanediyl, and butanediyl; and
m is an integer in a range of from 1 to 6.

11. The composition according to claim 1, wherein
R^{S31}, R^{S32}, R^{S33} are independently selected from the group consisting of methyl and ethyl;
R^{S34}, R^{S35}, R^{S36} are independently selected from the group consisting of H and methyl;
X^{S31} is selected from the group consisting of methanediyl, ethane-1,2-diyl, propane-1,3-diyl, and butane-1,4-diyl;
X^{S1} is selected from the group consisting of methanediyl, ethane-1,2-diyl, propane-1,3-diyl, or butane-1,4-diyl; and
m is an integer in a range of from 1 to 6.

12. The composition according to claim 1, wherein
R^{S41} is C₁ to C₄ alkyl;
R^{S42} is C₁ to C₄ alkyl;
R^{S51}, R^{S52} are independently selected from the group consisting of C₁ to C₄ alkyl.

13. The composition according to claim 1, wherein the second selectivity enhancer is a compound of formula S49 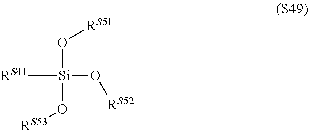
wherein
R^{S51}, R^{S52}, R^{S53} are independently selected from the group consisting of methyl, ethyl, propyl and butyl; and
R^{S41} is selected from the group consisting of methyl, ethyl, propyl and butyl.

14. The composition according to claim 1, wherein the additional selectivity enhancer is present in an amount of from 0.005 to 2% by weight.

15. The composition according to claim 1, wherein the concentration of the oxidizer is of from 1 to 10% by weight for etching the first silicon germanium layer in the presence of the silicon layer.

16. The composition according to claim 1, wherein the concentration of the oxidizer is of from 0.2 to 5% by weight for etching the first silicon germanium layer in the presence of the second silicon germanium layer.

17. A method of using a composition according to claim 1, the method comprising using the composition for selectively etching a first silicon germanium layer having a first germanium content in the presence of a silicon layer or a second silicon germanium layer having a second germanium content and optionally a silicon oxide layer, wherein the first germanium content is higher than the second germanium content.

18. A process of selectively removing a first silicon germanium alloy layer having a first germanium content from a surface of a microelectronic device relative to a silicon layer or a second silicon germanium layer having a second germanium content, and optionally a silicon oxide layer, wherein the first germanium content is higher than the second germanium content, the process comprising:
(a) providing a microelectronic device surface that includes the layer comprising the silicon germanium alloy and the silicon layer and optionally the silicon oxide layer,
(b) providing a composition according to claim 1, and
(c) contacting the surface with the composition for a time and at a temperature effective to selectively remove the layer comprising silicon-germanium relative to the layer comprising or consisting of Si and optionally the silicon oxide layer.

19. A process for the manufacture of a semiconductor device, comprising the process of selectively removing the first silicon germanium alloy layer having the first germanium content from the surface relative to the silicon layer or the second silicon germanium alloy layer having a second germanium content and optionally a silicon oxide layer according to claim 18.

20. The composition according to claim 1, wherein the oxidizing agent is a hydrogen peroxide.
